(19) United States
(12) Patent Application Publication
(10) Pub. No.: US 2022/0274222 A1
(43) Pub. Date: Sep. 1, 2022

(54) GRINDING APPARATUS

(71) Applicant: DISCO CORPORATION, Tokyo (JP)

(72) Inventors: Yohei WAKABAYASHI, Tokyo (JP); Osamu NAGAI, Tokyo (JP)

(21) Appl. No.: 17/652,537

(22) Filed: Feb. 25, 2022

(30) Foreign Application Priority Data
Mar. 1, 2021 (JP) 2021-031794

(51) Int. Cl. B24B 7/04; B24B 49/03; H01L 21/304

(52) U.S. Cl. CPC B24B 7/04; B24B 49/03; H01L 21/304

(57) ABSTRACT

A grinding apparatus includes a chuck table, a grinding unit, a thickness measuring device for measuring a thickness of the workpiece, and a control unit. The thickness measuring device includes a measuring unit for measuring the thickness of the workpiece and a measuring unit moving mechanism for moving the measuring unit back and forth on a measuring track. The control unit controls the measuring unit to measure thicknesses of the workpiece at various points thereon while moving the measuring unit back and forth on the measuring track, calculates a cross-sectional shape of the workpiece from average values of thickness values measured by the measuring unit in a forward stroke on the measuring track and thickness values measured by the measuring unit in a return stroke on the measuring track, and calculates a tilt adjustment variable for a table rotational axis according to the calculated cross-sectional shape.

### BACKGROUND OF THE INVENTION

### Field of the Invention

The present invention relates to a grinding apparatus for grinding a workpiece such as a semiconductor wafer held on a chuck table, the grinding apparatus being capable of adjusting the tilt of a table rotational axis of the chuck table.

### Description of the Related Art

Device chips including such devices as integrated circuits (ICs) and large-scale-integration (LSI) circuits are fabricated from wafers in the shape of circular plates. Specifically, a plurality of devices are built on the face side of a wafer, and then the reverse side of the wafer is ground to thin down the wafer. Thereafter, the wafer is divided into individual device chips incorporating the respective devices. Such workpieces as wafers are ground on a grinding apparatus (see Japanese Patent Laid-open No. 2009-141176). The grinding apparatus has a chuck table for holding a workpiece thereon and a grinding unit for grinding the workpiece held on the chuck table. The grinding unit includes a grinding wheel having an annular array of grindstones that are fixed thereto and that lie in a plane substantially parallel to the holding surface of the chuck table that holds the workpiece thereon.

The grinding apparatus can rotate the chuck table about a table rotational axis extending centrally through the holding surface and rotate the grinding wheel to turn the grindstones along an annular track. When the grinding unit is lowered to bring the grindstones into contact with the workpiece on the chuck table while the chuck table and the grinding wheel are rotating, the grindstones grind the workpiece. The holding surface of the chuck table is a gradually inclined conical surface. The tilt of the table rotational axis is determined to make one of the generators of the holding surface that is closest to a plane of rotation that includes the annular track, parallel to the plane of rotation. The tilt of the table rotational axis is preadjusted to cause the surface of the workpiece that has been ground by the grindstones to have a uniformly height. Heretofore, it has been customary to grind a wafer with the grindstones in a test, then measure a thickness distribution of the workpiece, and adjust the tilt of the table rotational axis in reference to the measured thickness distribution. However, the wafer that has been ground in the test before the tilt of the table rotational axis is adjusted tends to be irregular in thickness, and is thrown away for being a material unsuitable for fabricating device chips.

There has been proposed a method of temporarily stopping grinding a workpiece, retracting the grinding wheel away from the workpiece, measuring the thicknesses of various portions of the workpiece with a thickness measuring device, adjusting the tilt of the table rotational axis in reference to the measured thicknesses, and then resuming the grinding process (see Japanese Patent Laid-open No. 2013-119123). However, though the proposed method is effective to eliminate wasted workpieces, it is likely to lower the processing efficiency because the grinding process is temporarily suspended. According to another proposed method (Japanese Patent Laid-open No. 2016-184604), the thicknesses of various portions of a workpiece are monitored with a thickness measuring device while a measuring unit, i.e., a sensor, of the thickness measuring device is being moved over the workpiece when the workpiece is ground. However, since grindstones grind the workpiece at all times in a central portion of the workpiece, the measuring unit cannot gain access to the central portion of the workpiece, and hence the thickness measuring device is unable to measure the thickness of the central portion of the workpiece.

According to one solution, a plurality of data maps representing typical examples of the cross-sectional shapes of workpieces are stored in a control unit, and, with use of the stored data map, the thickness of a central portion of a workpiece can be predicted according to the cross-sectional shape of a portion of the workpiece other than the central portion thereof. Specifically, the cross-sectional shape of a portion of the workpiece other than the central portion thereof is checked against the data maps stored in the control unit, and one of the data maps that is closest to the cross-sectional shape is selected. Then, the tilt of the table rotational axis is adjusted according to the selected data map. This method does not require that the grinding process for the workpiece be temporarily suspended.

### SUMMARY OF THE INVENTION

However, inasmuch as the grinding process is continuously in progress while the measuring unit of the thickness measuring device is being moved over the surface being ground of the workpiece to measure the thicknesses of various portions of the workpiece, the thicknesses of those portions are measured at different times. In other words, the proposed method is unable to obtain an accurate thickness distribution over the entire surface of the workpiece at a certain point of time. Since the data maps of the cross-sectional shapes of workpieces do not assume that the grinding process is in progress, the thickness distribution of a workpiece that is measured by the thickness measuring device cannot be checked against the data maps to a nicety.

It is therefore an object of the present invention to provide a grinding apparatus that is capable of measuring a thickness distribution of a workpiece being ground and adjusting the relative tilt of the table rotational axis of a chuck table with respect to a spindle highly accurately, in reference to the measured thickness distribution.

In accordance with an aspect of the present invention, there is provided a grinding apparatus including a chuck table that has a conical holding surface for holding a workpiece thereon and that is rotatable about a table rotational axis extending centrally through the holding surface, a grinding unit including a grinding wheel having a plurality of grindstones arranged in an annular array on a surface facing the holding surface of the chuck table, a spindle having a lower end on which the grinding wheel is mounted, and a lifting and lowering mechanism for lifting and lowering the spindle, the grinding unit being capable of grinding the workpiece held on the holding surface of the chuck table while the chuck table is rotating about the table rotational axis, in an area of the workpiece extending from a center of the workpiece to an outer circumferential edge thereof, a tilt adjustment unit for adjusting a relative tilt of the table rotational axis and the spindle, a thickness measuring device for measuring a thickness of the workpiece held on the chuck table, and a control unit. In the grinding apparatus, the thickness measuring device includes a measuring unit for measuring a thickness of the workpiece while facing a portion of an upper surface of the workpiece to be ground by the grinding unit, and a measuring unit moving mechanism for moving the measuring unit back and forth on a measuring track between a position above the outer circumferential edge of the workpiece held on the chuck table and a position above the workpiece out of physical interference with the grinding unit, and the control unit includes a grinding controlling section for rotating the chuck table holding the workpiece thereon about the table rotational axis and controlling the lifting and lowering mechanism to lower the spindle while rotating the grinding wheel of the grinding unit about an axis of the spindle, to bring the grindstones into abrasive contact with the upper surface of the workpiece and thereby grind the workpiece, a cross-sectional shape calculating section for controlling the measuring unit to measure thicknesses of the workpiece at various points thereon while controlling the measuring unit moving mechanism to move the measuring unit back and forth on the measuring track, calculating average thickness values representing average values of measured thickness values acquired when the measuring unit measures the thickness of the workpiece in forward strokes on the measuring track and measured thickness values acquired when the measuring unit measures the thickness of the workpiece in return strokes on the measuring track, and calculating a cross-sectional shape of the workpiece from the average thickness values at the various points, and a tilt adjustment variable calculating section for calculating an adjustment variable for the relative tilt of the table rotational axis and the spindle to be adjusted by the tilt adjustment unit in order to bring the workpiece ground by the grindstones close to a finished shape, according to the cross-sectional shape of the workpiece.

Preferably, the control unit further includes a cross-sectional shape interpolating section for calculating a cross-sectional shape of a central portion of the workpiece according to the least-squares method from the cross-sectional shape of the workpiece calculated by the cross-sectional shape calculating section and interpolating the cross-sectional shape of the workpiece according to the calculated cross-sectional shape of the central portion of the workpiece, and the tilt adjustment variable calculating section calculates an adjustment variable for the relative tilt of the table rotational axis and the spindle according to the cross-sectional shape of the workpiece interpolated by the cross-sectional shape interpolating section.

In accordance with another aspect of the present invention, there is provided a grinding apparatus including a chuck table that has a conical holding surface for holding a workpiece thereon and that is rotatable about a table rotational axis extending centrally through the holding surface, a grinding unit including a grinding wheel having a plurality of grindstones arranged in an annular array on a surface facing the holding surface of the chuck table, a spindle having a lower end on which the grinding wheel is mounted, and a lifting and lowering mechanism for lifting and lowering the spindle, the grinding unit being capable of grinding the workpiece held on the holding surface of the chuck table while the chuck table is rotating about the table rotational axis, in an area of the workpiece extending from a center of the workpiece to an outer circumferential edge thereof, a tilt adjustment unit for adjusting a relative tilt of the table rotational axis and the spindle, a thickness measuring device for measuring a thickness of the workpiece held on the chuck table, and a control unit. The thickness measuring device includes a measuring unit for measuring a thickness of the workpiece while facing a portion of an upper surface of the workpiece to be ground by the grinding unit, and a measuring unit moving mechanism for moving the measuring unit back and forth on a measuring track between a position above the outer circumferential edge of the workpiece held on the chuck table and a position above the workpiece out of physical interference with the grinding unit, and the control unit includes a grinding controlling section for rotating the chuck table holding the workpiece thereon about the table rotational axis and controlling the lifting and lowering mechanism to lower the spindle while rotating the grinding wheel of the grinding unit about an axis of the spindle, to bring the grindstones into abrasive contact with the upper surface of the workpiece and thereby grind the workpiece, a cross-sectional shape calculating section for controlling the measuring unit to measure thicknesses of the workpiece at various points thereon while controlling the measuring unit moving mechanism to move the measuring unit back and forth on the measuring track, and calculating a cross-sectional shape of a portion of the workpiece other than a central portion thereof from measured thickness values, a tilt adjustment variable calculating section for calculating an adjustment variable for the relative tilt of the table rotational axis and the spindle to be adjusted by the tilt adjustment unit in order to bring the workpiece ground by the grindstones close to a finished shape according to the cross-sectional shape of the workpiece, and a cross-sectional shape interpolating section for calculating a cross-sectional shape of the central portion of the workpiece according to the least-squares method from the cross-sectional shape of the portion of the workpiece other than the central portion thereof calculated by the cross-sectional shape calculating section and interpolating the cross-sectional shape of the workpiece according to the calculated cross-sectional shape of the central portion of the workpiece, and the tilt adjustment variable calculating section calculates an adjustment variable for the relative tilt of the table rotational axis and the spindle according to the cross-sectional shape of the workpiece interpolated by the cross-sectional shape interpolating section.

Preferably, the measuring unit is a non-contact-type sensor for measuring the thickness of the workpiece while staying out of physical contact with the workpiece.

Preferably, the measuring unit includes a plurality of sensors for measuring the thickness of the workpiece.

In the grinding apparatus according to the aspects of the present invention, while the grindstones are grinding the workpiece, the measuring unit of the thickness measuring device measures thicknesses of the workpiece at various points thereon while moving back and forth on the measuring track. When the measuring unit reaches an end of the measuring track, the thicknesses of the workpiece at the various points thereon are calculated, obtaining a thickness distribution of the workpiece, i.e., a cross-sectional shape thereof, at the time. The thicknesses of the workpiece at the various points thereon can thereby be calculated to a nicety without being affected by the differences between the measuring times upon movement of the measuring unit, making it possible to adjust the relative tilt of the table rotational axis and the spindle highly accurately.

According to the present invention, there is thus provided a grinding apparatus that is capable of measuring a thickness distribution of a workpiece being ground and adjusting the relative tilt of the table rotational axis with respect to the spindle highly accurately, according to the measured thickness distribution.

The above and other objects, features and advantages of the present invention and the manner of realizing them will become more apparent, and the invention itself will best be understood from a study of the following description and appended claims with reference to the attached drawings showing a preferred embodiment of the present invention.

### BRIEF DESCRIPTION OF THE DRAWINGS

FIG. 1 is a perspective view schematically illustrating a grinding apparatus according to an embodiment of the present invention and a workpiece to be ground by the grinding apparatus;

FIG. 2 is a fragmentary cross-sectional view schematically illustrating a grinding unit and a chuck table of the grinding apparatus;

FIG. 3 is a plan view schematically illustrating the positional relation between the chuck table and an annular track along which grindstones are moved;

FIG. 4A is a graph schematically illustrating an element of a thickness distribution of the workpiece;

FIG. 4B is a graph schematically illustrating another element of a thickness distribution of the workpiece;

FIG. 5 is a graph illustrating the relation between the position of a detecting unit of a thickness detecting device and the thickness of the workpiece; and

FIG. 6 is a graph schematically illustrating changes over time of a deviation of the thickness of the workpiece being ground and changes over time of a tilt adjustment variable for a table rotational axis.

### DETAILED DESCRIPTION OF THE PREFERRED EMBODIMENT

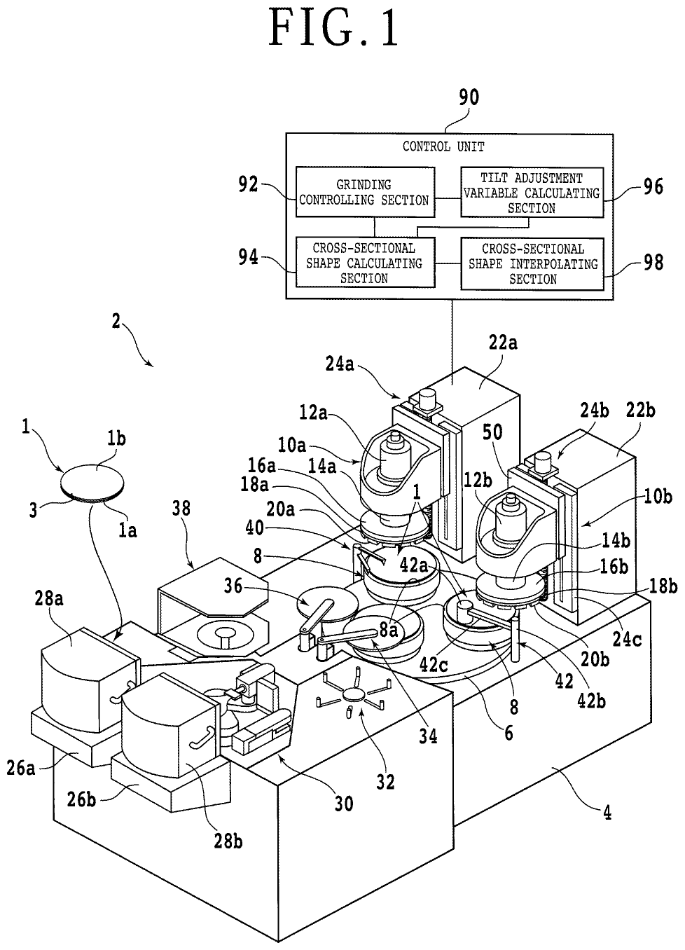

A grinding apparatus according to a preferred embodiment of the present invention will be described hereinbelow with reference to the accompanying drawings. The grinding apparatus according to the present embodiment grinds a workpiece to thin it down. FIG. 1 schematically illustrates the grinding apparatus, denoted by 2, and the workpiece, denoted by 1. The workpiece 1 is, for example, a wafer or the like substantially in the shape of a circular plate made of silicon (Si), silicon carbide (SiC), gallium nitride (GaN), gallium arsenide (GaAs), or any of other semiconductor materials. However, the workpiece 1 is not limited to these materials. A plurality of devices are formed in rows and columns on a face side 1a of the workpiece 1, and then the workpiece 1 is divided along the rows and columns into individual device chips that contain the respective devices. Providing the workpiece 1 is thinned down by being ground on a reverse side 1b thereof, i.e., a surface to be ground of the workpiece 1, by the grinding apparatus 2, thin device chips are finally fabricated from the workpiece 1. A tape-shaped protective member 3 for protecting the devices, etc., formed on the face side 1a is affixed to the face side 1a of the workpiece 1 to be ground by the grinding apparatus 2.

The grinding apparatus 2 according to the present embodiment will be described in detail below with reference to FIG. 1. The grinding apparatus 2 includes a base 4 supporting components thereof. Two cassette rest tables 26a and 26b are fixed to a front end of the base 4. A cassette 28a housing workpieces 1 to be ground is placed on the cassette rest table 26a, whereas a cassette 28b housing workpieces 1 that have been ground is placed on the cassette rest table 26b. A wafer delivery robot 30 is mounted on the base 4 at a position adjacent to the cassette rest tables 26a and 26b. The wafer delivery robot 30 unloads a workpiece 1 from the cassette 28a placed on the cassette rest table 26a and delivers the workpiece 1 with the reverse side 1b facing upwardly to a positioning table 32 disposed on the base 4 at a position adjacent to the wafer delivery robot 30. The positioning table 32 has a plurality of radially movable positioning pins arranged in an annular array. When the workpiece 1 is placed on a central rest area of the positioning table 32, the positioning table 32 positions the workpiece 1 at a predetermined position thereon by moving the positioning pins radially inwardly in ganged relation into engagement with the workpiece 1.

A loading arm 34 and an unloading arm 36 are disposed on an upper surface of the base 4 at respective positions adjacent to the positioning table 32. The workpiece 1 that has been positioned at the predetermined position on the positioning table 32 is delivered from the positioning table 32 by the loading arm 34. A turntable 6 shaped as a circular plate is rotatably mounted centrally on the upper surface of the base 4. The turntable 6 supports on its upper surface three chuck tables 8 that are angularly spaced circumferentially at 120° intervals. When the turntable 6 is turned about its central axis, the chuck tables 8 are angularly moved therewith while holding respective workpieces 1 delivered by the loading arm 34.

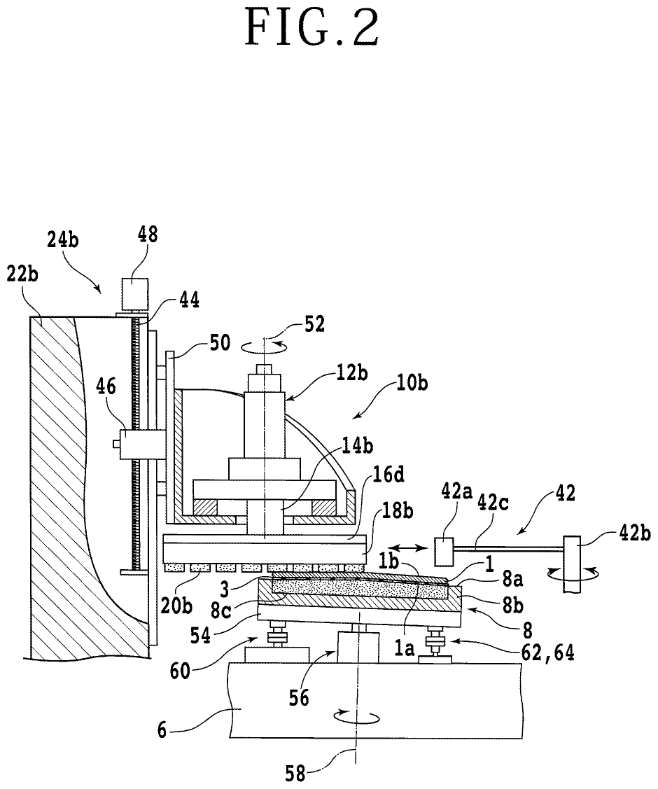

FIG. 2 schematically illustrates one of the chuck tables 8 in cross section. Since the three chuck tables 8 are structurally identical to each other, only one of them will be described below. The chuck table 8 includes a porous member 8c shaped as a circular plate having the same diameter as the workpiece 1 and a frame body 8b that is made of stainless steel and that has an upwardly exposed recess that is defined therein and that houses the porous member 8c therein. The frame body 8b has a suction channel (not illustrated) that is defined therein and that has an end reaching the bottom surface of the recess. The other end of the suction channel is held in fluid communication with a suction source (not illustrated). When the workpiece 1 is placed on the porous member 8c of the chuck table 8 and the suction source is actuated, the suction source applies a negative pressure through the suction channel and the porous member 8c to the workpiece 1 placed thereon, holding the workpiece 1 under suction on the chuck table 8. The chuck table 8 has an upper surface acting a holding surface 8a provided by the porous member 8c for holding the workpiece 1 under suction thereon. The holding surface 8a is a conical surface that is highly gradually inclined, as described later on.

A rotary actuator 56 such as an electric motor is coupled to a bottom portion 54 of the chuck table 8 for rotating the chuck table 8 about a table rotational axis 58 extending centrally through the holding surface 8a. The bottom portion 54 of the chuck table 8 is supported on a plurality of support shafts in such a manner that the bottom portion 54 of the chuck table 8 will not be prevented from rotating by the support shafts. Specifically, the support shafts include one fixed shaft 60 and two extensible and contractible adjustment shafts 62 and 64. The tilt of the holding surface 8a, i.e., the tilt of the table rotational axis 58, can be adjusted by adjusting the lengths of the adjustment shafts 62 and 64. In other words, the adjustment shafts 62 and 64 jointly function as a tilt adjustment unit for adjusting the tilt of the table rotational axis 58.

The grinding apparatus 2 will further be described below with reference to FIG. 1. The workpiece 1 is loaded onto and unloaded from a chuck table 8 that is positioned in a wafer loading/unloading region over the turntable 6. In the wafer loading/unloading region, the workpiece 1 can be loaded onto the chuck table 8 by the loading arm 34 and can be unloaded from the chuck table 8 by the unloading arm 36. After the workpiece 1 has been loaded with the reverse side 1b facing upwardly onto the chuck table 8 positioned in the wafer loading/unloading region by the loading arm 34, the turntable 6 is turned to move the chuck table 8 with the workpiece 1 placed thereon to a next rough-grinding region positioned over the turntable 6 adjacent to the wafer loading/unloading region.

A first grinding unit 10a for rough-grinding the reverse side 1b of the workpiece 1 held on the chuck table 8 in the rough-grinding region is disposed outside of the turntable 6 on a rear upper surface of the base 4. The workpiece 1 held on the chuck table 8 in the rough-grinding region is rough-ground by the first grinding unit 10a. After the workpiece 1 has been rough-ground by the first grinding unit 10a, the turntable 6 is turned to move the chuck table 8 to a finish-grinding region over the turntable 6 adjacent to the rough-grinding region. A second grinding unit 10b for finish-grinding the reverse side 1b of the workpiece 1 held on the chuck table 8 in the finish-grinding region is disposed adjacent to the first grinding unit 10a outside of the turntable 6 on a rear upper surface of the base 4. The workpiece 1 held on the chuck table 8 in the finish-grinding region is finish-ground by the second grinding unit 10b. After the workpiece 1 has been finish-ground by the second grinding unit 10b, the turntable 6 is turned to move the chuck table 8 back to the wafer loading/unloading region where the workpiece 1 is unloaded from the chuck table 8 by the unloading arm 36.

A spinner cleaning device 38 for cleaning and spin-drying the ground workpiece 1 is disposed near the unloading arm 36 on the upper surface of the base 4 and the wafer delivery robot 30 on the base 4. The ground workpiece 1 that has been unloaded from the chuck table 8 by the unloading arm 36 is delivered to the spinner cleaning device 38, and cleaned and spin-dried by the spinner cleaning device 38. After the workpiece 1 has been cleaned and spin-dried by the spinner cleaning device 38, the workpiece 1 is delivered from the spinner cleaning device 38 and placed into the cassette 28b placed on the cassette rest table 26b by the wafer delivery robot 30. Two columns 22a and 22b that are disposed adjacent to each other are erected on a rear portion of the base 4. The first grinding unit 10a is vertically movably mounted on a front surface of the column 22a, and the second grinding unit 10b is vertically movably mounted on a front surface of the column 22b.

The first grinding unit 10a includes a first spindle 14a extending in vertical directions and a spindle motor 12a connected to an upper end of the first spindle 14a. The second grinding unit 10b includes a second spindle 14b extending in vertical directions and a spindle motor 12b connected to an upper end of the second spindle 14b. The first grinding unit 10a also includes a first lifting and lowering mechanism 24a supporting the components of the first grinding unit 10a that include the first spindle 14a for movement along the vertical directions. The second grinding unit 10b also includes a second lifting and lowering mechanism 24b supporting the components of the second grinding unit 10b that include the second spindle 14b for movement along the vertical directions. The first and second spindles 14a and 14b may have their orientations adjustable.

FIGS. 1 and 2 schematically illustrate the second lifting and lowering mechanism 24b. The second lifting and lowering mechanism 24b includes a pair of guide rails extending along the vertical directions on the front surface of the column 22b, a lifting and lowering plate 50 slidably supported on the guide rails for movement therealong, and a ball screw 44 that is disposed between and extends parallel to the guide rails. The components of the second grinding unit 10b are supported on a front surface of the lifting and lowering plate 50. A nut 46 is mounted on a rear surface of the lifting and lowering plate 50 and operatively threaded over the ball screw 44. The ball screw 44 has an upper end connected to a stepping motor 48. When the stepping motor 48 is energized, it rotates the ball screw 44 about its central axis, causing the nut 46 to lift or lower the lifting and lowering plate 50. The first lifting and lowering mechanism 24a is identical in structure to the second lifting and lowering mechanism 24b.

As illustrated in FIG. 1, a wheel mount 16a shaped as a circular plate is mounted on the lower end of the first spindle 14a. A first grinding wheel 18a is fixed to a lower surface of the wheel mount 16a. In other words, the first grinding wheel 18a is fixedly mounted on the lower end of the first spindle 14a. A plurality of first grindstones 20a arranged in an annular array are mounted on the surface, i.e., the lower surface, of the first grinding wheel 18a that faces the holding surface 8a of the chuck table 8 that is positioned in the rough-grinding region. A wheel mount 16b shaped as a circular plate is mounted on the lower end of the second spindle 14b. A second grinding wheel 18b is fixed to a lower surface of the wheel mount 16b. In other words, the second grinding wheel 18b is fixedly mounted on the lower end of the second spindle 14b. A plurality of second grindstones 20b arranged in an annular array are mounted on the surface, i.e., the lower surface, of the second grinding wheel 18b that faces the holding surface 8a of the chuck table 8 that is positioned in the finish-grinding region.

When the spindle motor 12a is energized, the first spindle 14a is rotated about its central axis, rotating the first grinding wheel 18a to move the first grindstones 20a on and along a first annular track. Then, the first lifting and lowering mechanism 24a is actuated to lower the first spindle 14a and bring the first grindstones 20a into abrasive contact with the reverse side 1b, i.e., the upper surface, of the workpiece 1 held on the chuck table 8 in the rough-grinding region, thereby grinding the workpiece 1. When the spindle motor 12b is energized, the second spindle 14b is rotated about its central axis, rotating the second grinding wheel 18b to move the second grindstones 20b on and along a second annular track. Then, the second lifting and lowering mechanism 24b is actuated to lower the second spindle 14b and bring the second grindstones 20b into abrasive contact with the reverse side 1b, i.e., the upper surface, of the workpiece 1 held on the chuck table 8 in the finish-grinding region, thereby grinding the workpiece 1.

In the first grinding unit 10a, the lifting and lowering mechanism 24a grinding-feeds the first grinding unit 10a at a relatively high speed to enable the first grindstones 20a of the first grinding unit 10a to perform rough grinding on the workpiece 1 on the chuck table 8 in the rough-grinding region. When the workpiece 1 is rough-ground by the first grinding unit 10a, most of the total material to be ground off the workpiece 1 until the workpiece 1 is ground to a finished thickness is removed. In the second grinding unit 10b, the lifting and lowering mechanism 24b grinding-feeds the second grinding unit 10b at a relatively low speed to enable the second grindstones 20b of the second grinding unit 10b to perform finish grinding on the workpiece 1 on the chuck table 8 in the finish-grinding region. When the workpiece 1 is finish-ground by the second grinding unit 10b, the workpiece 1 is ground to the finished thickness, so that surface irregularities are removed from the reverse side 1b. Each of the first grindstones 20a and the second grindstones 20b contains abrasive grains made of diamond or the like and a binder in which the abrasive grains are dispersed and secured. The abrasive grains contained in the second grindstones 20b used for finish grinding should preferably be of a grain size smaller than that of the abrasive grains contained in the first grindstones 20a used for rough grinding. The abrasive grains of the thus selected grain size allow the first grindstones 20a to rough-grind the workpiece 1 more quickly and also allows the second grindstones 20b to finish-grind the workpiece 1 to higher quality.

A first thickness measuring device 40 for measuring the thickness of the workpiece 1 rough-ground by the first grinding unit 10a is disposed on the upper surface of the base 4 near the first grinding unit 10a. Similarly, a second thickness measuring device 42 for measuring the thickness of the workpiece 1 finish-ground by the second grinding unit 10b is disposed on the upper surface of the base 4 near the second grinding unit 10b.

The first thickness measuring device 40 is, for example, a contact-type thickness measuring device for measuring the thickness of the workpiece 1 while physically contacting the reverse side 1b of the workpiece 1. The contact-type thickness measuring device includes two probes extending over the chuck table 8 in the rough-grinding region, for example. Each of the probes includes an arm extending horizontally and a contact finger extending downwardly from a distal end of the arm. One of the probes measures the height of the reverse side 1b of the workpiece 1 by keeping the lower end of the contact finger thereof in contact with the reverse side 1b of the workpiece 1. The other probe measures the height of the holding surface 8a of the chuck table 8 by keeping the lower end of the contact finger thereof in contact with the holding surface 8a. The workpiece 1 is placed and held on the holding surface 8a of the chuck table 8 with the protective member 3 interposed therebetween. Hence, the contact-type thickness measuring device can calculate the total thickness of the workpiece 1 and the protective member 3 from the difference between the measured height of the reverse side 1b of the workpiece 1 and the measured height of the holding surface 8a of the chuck table 8.

The second thickness measuring device 42 is, for example, a non-contact-type thickness measuring device for measuring the thickness of the workpiece 1 while staying out of physical contact with the reverse side 1b of the workpiece 1. The non-contact-type thickness measuring device includes a measuring unit 42a disposed directly above the reverse side 1b of the workpiece 1 on the chuck table 8 in the finish-grinding region. The non-contact-type thickness measuring device measures the height of the reverse side 1b of the workpiece 1 by transmitting ultrasonic waves or probe light from the measuring unit 42a to the reverse side 1b of the workpiece 1, detecting reflected ultrasonic waves or probe light from the reverse side 1b with the measuring unit 42a, and analyzing the detected ultrasonic waves or probe light. Hence, the measuring unit 42a is a non-contact-type sensor.

The non-contact-type second thickness measuring device 42 has, for example, a rotatable shaft 42b erected from the upper surface of the base 4 of the grinding apparatus 2 and an arm 42c extending horizontally from an upper end of the shaft 42b. The measuring unit 42a is fixed to a distal end of the arm 42c. An unillustrated rotating mechanism including a piston, an electric motor, or the like is connected to a lower end of the shaft 42b for rotating the shaft 42b about its central axis. When the shaft 42b is rotated about its central axis by the rotating mechanism, the measuring unit 42a is moved on and along an arcuate measuring track around the shaft 42b. Stated otherwise, the grinding apparatus 2 has a measuring unit moving mechanism for moving the measuring unit 42a back and forth on and along the arcuate measuring track over the workpiece 1 on the chuck table 8 in the finish-grinding region. While the reverse side 1b of the workpiece 1 is being ground by the second grinding unit 10b, the measuring unit 42a is movable over the reverse side 1b of the workpiece 1 and can measure various portions of the reverse side 1b.

However, the measuring unit 42a cannot move into physical interference with the second grinding unit 10b as it grinds the workpiece 1. Since the second grindstones 20b keep contacting a central portion of the workpiece 1 while grinding the workpiece 1, the measuring unit 42a is unable to enter a space above the central portion of the workpiece 1 at any time. Specifically, the measuring unit moving mechanism moves the measuring unit 42a back and forth on the arcuate measuring track between a position above the outer circumferential edge of the workpiece 1 on the chuck table 8 and a position above the workpiece 1 out of physical interference with the second grinding unit 10b.

The grinding apparatus 2 further includes a control unit 90 for controlling various components thereof. The control unit 90 controls, for example, the turntable 6, the chuck tables 8, the first and second grinding units 10a and 10b, the wafer delivery robot 30, the positioning table 32, the loading arm 34, the unloading arm 36, the spinner cleaning device 38, etc. The control unit 90 includes a computer including a processing device such as a central processing unit (CPU) or a microprocessor and a storage device such as a flash memory or a hard disk drive. When the processing device operates according to software represented by programs, etc., stored in the storage device, the control unit 90 functions as specific means in which the software and the processing device work together. The control unit 90 stores processing conditions under which various workpieces 1 are to be ground by the first and second grinding units 10a and 10b, various pieces of information, etc., in the storage device. The processing conditions stored in the storage device include information representing the types, sizes, and thicknesses to be achieved by rough and finish grinding, of workpieces 1 to be processed, i.e., ground, rotational speeds of the spindles 14a and 14b, etc.

As illustrated in FIG. 2, etc., the holding surface 8a of the chuck table 8 includes an upwardly protruding conical surface that is highly gradually inclined with its center at the apex. When the chuck table 8 holds the workpiece 1 under suction thereon, the workpiece 1 is slightly deformed in conformity with the conical holding surface 8a. The workpieces 1, the chuck tables 8, etc., illustrated in various figures of the drawings have their shapes exaggerated for illustrative purposes. A finish-grinding process to be carried out by the second grinding unit 10b illustrated in FIG. 2 will be described below.

For finish-grinding the workpiece 1 with the second grinding unit 10b, the chuck table 8 in the finish-grinding region is rotated about the table rotational axis 58 and the second spindle 14b is lowered while being rotated about its central axis to bring the second grindstones 20b into abrasive contact with the reverse side 1b of the workpiece 1. While the second grindstones 20b are grinding an arcuate area of the workpiece 1 from its center to outer circumferential edge, the workpiece 1 on the chuck table 8 is rotated about the table rotational axis 58, causing the second grindstones 20b to grind the reverse side 1b of the workpiece 1 in its entirety.

In order to make the face side 1a and the reverse side 1b of the workpiece 1 parallel to each other, the tilt of the table rotational axis 58 is determined to make one of the generators of the conical holding surface 8a that is closest to a plane of rotation that includes the annular track of the second grindstones 20b, parallel to the plane of rotation. While the second grindstones 20b are grinding the reverse side 1b of the workpiece 1, the second thickness measuring device 42 monitors the thickness of the workpiece 1. When the workpiece 1 has been ground to a predetermined thickness, the second lifting and lowering mechanism 24b stops lowering the second spindle 14b, bringing the finish-grinding process on the workpiece 1 to an end.

If the tilt of the table rotational axis 58 of the chuck table 8 is not appropriate, the workpiece 1 does not have a uniform thickness distribution, and suffers a thickness deviation, so that the face side 1a and the reverse side 1b of the workpiece 1 do not lie parallel to each other. While the workpiece 1 is being ground, therefore, the measuring unit 42a of the second thickness measuring device 42 is moved to measure the thicknesses of various portions of the workpiece 1. In this manner, the thickness distribution of the workpiece 1 is monitored. When the measured thickness distribution of the workpiece 1 becomes problematic, the tilt adjustment unit may be used to adjust the tilt of the table rotational axis 58. However, since the second grindstones 20b grind the workpiece 1 at all times in the central portion thereof, the measuring unit 42a cannot access the central portion of the workpiece 1 and hence cannot measure the thickness of the central portion of the workpiece 1.

According to one solution, a plurality of data maps representing an example of the cross-sectional shape of the workpiece 1 are stored in the control unit 90 or the like, and, with use of the stored data map, the thickness of the central portion of the workpiece 1 can be predicted according to the cross-sectional shape of a portion of the workpiece 1 other than the central portion thereof. Specifically, the cross-sectional shape of a portion of the workpiece 1 other than the central portion thereof is checked against the data maps stored in the control unit 90, and one of the data maps that is closest to the cross-sectional shape is selected. Then, a thickness distribution of the workpiece 1 in its entirety is predicted according to the selected data map, and the tilt of the table rotational axis 58 is adjusted according to the predicted thickness distribution. However, inasmuch as the grinding process is continuously in progress while the measuring unit, i.e., sensor, 42a of the second thickness measuring device 42 is being moved over the surface being ground of the workpiece 1 to measure the thicknesses of various portions of the workpiece 1, the thicknesses of those portions are measured at different times. In other words, the proposed method is unable to obtain an accurate thickness distribution over the entire surface of the workpiece 1 at a certain time. Since the data maps of the cross-sectional shape of the workpiece 1 do not assume that the grinding process is in progress, the thickness distribution of the workpiece 1 that is measured by the thickness measuring device 42 cannot be checked against the data maps to a nicety.

On the other hand, the grinding apparatus 2 according to the present embodiment predicts a thickness distribution of the workpiece 1 in its entirety at a certain point of time while the workpiece 1 is changing its thickness during the grinding process. Then, depending on the predicted thickness distribution of the workpiece 1, the grinding apparatus 2 actuates the tilt adjustment unit to adjust the tilt of the table rotational axis 58, and grinds the workpiece 1 with the adjusted tilt of the table rotational axis 58 to make the ground workpiece 1 free of thickness deviations. Configurational details of the grinding apparatus 2 that contribute to the prediction of a thickness distribution of the workpiece 1 in its entirety at a certain point of time will be described in detail below. The prediction of a thickness distribution of the workpiece 1 in its entirety on the grinding apparatus 2 is carried out by the control unit 90 that controls the components of the grinding apparatus 2. The control unit 90 then determines details as to how to operate the tilt adjustment unit.

The control unit 90 includes a grinding controlling section 92 (see FIG. 1) for controlling components of the grinding apparatus 2 to grind workpieces 1 in the rough-grinding region and the finish-grinding region. For grinding the workpieces 1, the grinding controlling section 92 rotates the chuck tables 8 that are holding the workpieces 1 thereon about their table rotational axes 58 and also rotates the first and second spindles 14a and 14b of the first and second grinding units 10a and 10b about their central axes to rotate the grinding wheels 18a and 18b in unison therewith. Then, the grinding controlling section 92 controls the first and second lifting and lowering mechanisms 24a and 24b to lower first and second the spindles 14a and 14b, bringing the first and second grindstones 20a and 20b into abrasive contact with the upper surfaces, i.e., the reverse sides 1b, of the workpieces 1 to thereby grind the workpieces 1. The grinding controlling section 92 controls the components according to grinding conditions stored in the control unit 90. While the grinding process for the workpieces 1 is in progress, the grinding controlling section 92 monitors the respective thicknesses of the workpieces 1 with the first and second thickness measuring devices 40 and 42, and stops lowering the first and second spindles 14a and 14b when the workpieces 1 have been ground to a predetermined thickness, thus stopping grinding the workpieces 1. In addition, the grinding controlling section 92 also monitors the respective thickness distributions of the workpieces 1 with the first and second thickness measuring devices 40 and 42, and, upon detection of large thickness deviations of the workpieces 1, controls the tilt adjustment units to adjust the tilt of the table rotational axes 58.

For adjusting the tilt of the table rotational axes 58, the grinding controlling section 92 refers to the cross-sectional shapes of the workpieces 1. The control unit 90 also includes a cross-sectional shape calculating section 94 for calculating the cross-sectional shapes of the workpieces 1 from the thicknesses of various portions of the workpieces 1. The thickness of the workpiece 1 in the rough-grinding region is measured by the first thickness measuring device 40, whereas the thickness of the workpiece 1 in the finish-grinding region is measured by the measuring unit 42a of the second thickness measuring device 42 while the measuring unit 42a is being moved on and along the measuring track by the measuring unit moving mechanism. Further, the control unit 90 includes a tilt adjustment variable calculating section 96 for calculating tilt adjustment variables or angles by which the tilt of the table rotational axes 58 is to be adjusted by the tilt adjustment units, in order to make the workpieces 1 ground by the first and second grindstones 20a and 20b close to a finished shape. The grinding controlling section 92 refers to the calculated tilt adjustment variables from the tilt adjustment variable calculating section 96 and controls the tilt adjustment units to adjust the tilt of the table rotational axes 58 in reference to the tilt adjustment variables.

The relation between deviations of a thickness distribution of a workpiece 1 in the grinding process and the tilt of the table rotational axis 58 will be described in detail below. Though the relation in a process for finish-grinding the workpiece 1 with the second grinding unit 10b will be described below, the relation in a process for rough-grinding a workpiece 1 with the first grinding unit 10a is similar to the relation in the finish-grinding process.

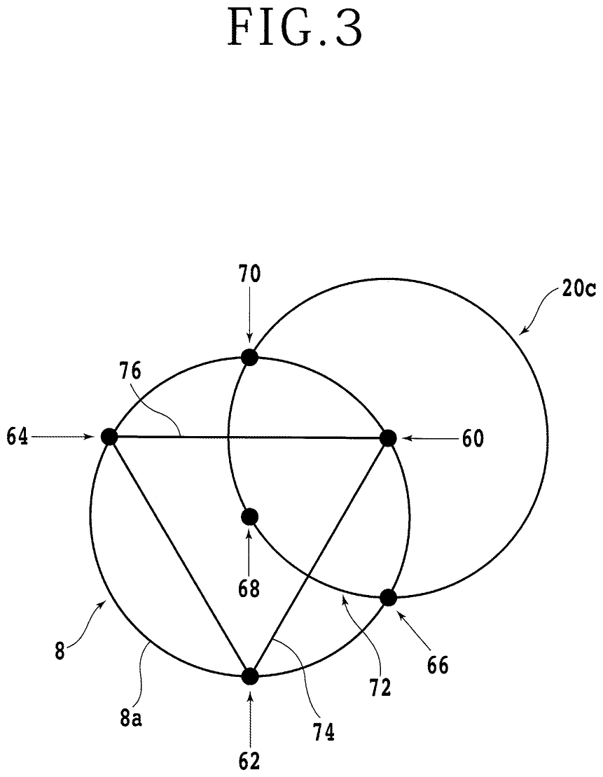

FIG. 3 schematically illustrates in plan the positional relation between the holding surface 8a of the chuck table 8 and the annular track 20c along which the second grindstones 20b on the second grinding wheel 18b are moved. In FIG. 3, the contour of the conical holding surface 8a of the chuck table 8 and the annular track 20c are schematically illustrated as circles. The circle that represents the annular track 20c is equal in diameter to the circle that represents the contour of the conical holding surface 8a of the chuck table 8. The table rotational axis 58 of the chuck table 8 passes through the center, denoted by 68, of the holding surface 8a.

FIG. 3 also illustrates the respective positions of the fixed shaft 60 and the two adjustment shafts 62 and 64. The fixed shaft 60 is positioned essentially below the center of the second grinding wheel 18b. The fixed shaft 60 and the two adjustment shafts 62 and 64 are disposed respectively at the vertexes of a regular triangle. The chuck table 8 is supported by the fixed shaft 60 and the adjustment shafts 62 and 64, with the adjustment shafts 62 and 64 functioning as the tilt adjustment unit, as described above. For example, when the adjustment shaft 64 is extended whereas the adjustment shaft 62 is not, the chuck table 8 changes its tilt by turning about a first axis 74 extending through the fixed shaft 60 and the adjustment shaft 62. On the other hand, when the adjustment shaft 62 is extended whereas the adjustment shaft 64 is not, the chuck table 8 changes its tilt by turning about a second axis 76 extending through the fixed shaft 60 and the adjustment shaft 64. In other words, the tilt of the table rotational axis 58 can be changed by extending or contracting the adjustment shafts 62 and 64.

For grinding the workpiece 1, the tilt adjustment unit adjust the tilt of the table rotational axis 58 to make a generator of the holding surface 8a that interconnects the center 68 of the holding surface 8a underlying the annular track 20c and an outer circumferential edge, denoted by 66, of the holding surface 8a, parallel to the annular track 20c. The second grindstones 20b that are being moved along the annular track 20c are bought into abrasive contact with the reverse side 1b of the workpiece 1 in a grinding area 72 between a position above the center 68 of the holding surface 8a and a position above the outer circumferential edge 66, grinding the reverse side 1b of the workpiece 1. The second grindstones 20b stay out of abrasive contact with the workpiece 1 in an area between the position above the center 68 of the holding surface 8a and a position above another outer circumferential edge 70 of the holding surface 8a.

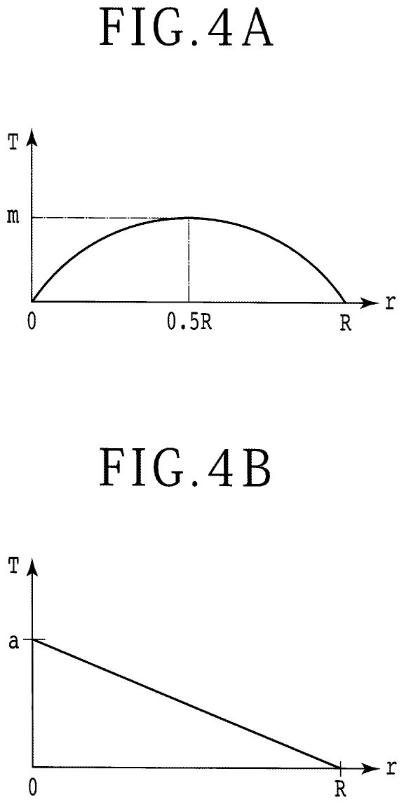

FIGS. 4A and 4B are graphs schematically illustrating thickness distributions of the workpiece 1 that are ground when the tilt of the table rotational axis 58 is not appropriate. In each of the graphs, the horizontal axis represents the distance from the center of the workpiece 1, and the vertical axis the thickness deviation of the workpiece 1. When the workpiece 1 is ground, the chuck table 8 is rotated about the table rotational axis 58, and the second grinding wheel 18b is rotated about the axis of the second spindle 14b. At this time, a circular area of the workpiece 1 that is spaced a certain distance from the center of the workpiece 1 is uniformly ground, so that the circular area of the workpiece 1 has a generally constant thickness distribution. Consequently, the thickness distribution of the workpiece 1 can be assessed from the relation between the distance from the center of the workpiece 1 and the thickness deviation of the workpiece 1, as indicated by the graphs of FIGS. 4A and 4B.

The thickness distribution indicated by the graph of FIG. 4B represents an example of thickness distribution that is developed if the grinding area 72 between the center 68 of the holding surface 8a and the outer circumferential edge 66 thereof is tilted in its entirety. This thickness distribution appears in a case where the annular track 20c of the second grindstones 20b and the generator interconnecting the center 68 of the holding surface 8a and the outer circumferential edge 66 thereof are not parallel to each other. More specifically, the thickness distribution indicated by the graph of FIG. 4B appears in a case where the distance between the holding surface 8a and the annular track 20c is larger at the center 68 of the holding surface 8a than at the outer circumferential edge 66 of the holding surface 8a. The difference between the thickness of the workpiece 1 at the center thereof and the thickness of the workpiece 1 at the outer circumferential edge thereof is indicated as a thickness deviation “a” in FIG. 4B. If the distance between the holding surface 8a and the annular track 20c is larger at the outer circumferential edge 66 of the holding surface 8a than at the center 68 of the holding surface 8a, then the thickness deviation “a” becomes a negative value.

In view of the cross-sectional shape of the workpiece 1 that is produced due to the thickness deviation “a,” the thickness deviation “a” may be called a “protruding deviation.” In order to eliminate the deviation of the thickness variation indicated by the graph of FIG. 4B, the length of the adjustment shaft 64 may mainly be adjusted to make the holding surface 8a and the annular track 20c parallel to each other. As illustrated in FIG. 4B, the thickness deviation can be expressed by a linear function of the distance from the center of the workpiece 1, represented by the horizontal axis, and the thickness deviation of the workpiece 1, represented by the vertical axis. This linear function means that the thickness deviation represented by the vertical axis is “a” when the distance from the center of the workpiece 1 represented by the horizontal axis is zero, and the thickness deviation “a” represented by the vertical axis is zero when the distance from the center of the workpiece 1 represented by the horizontal axis is R, i.e., the radius of the workpiece 1.

The thickness distribution indicated by the graph of FIG. 4A represents an example of thickness distribution that is developed if the second grindstones 20b grind the workpiece 1 to a shallow or deep depth centrally in the grinding area 72 between the center 68 of the holding surface 8a and the outer circumferential edge 66 thereof. In order to eliminate the deviation of the thickness variation indicated by the graph of FIG. 4A, the adjustment shaft 62 may be mainly adjusted whereas the adjustment shaft 64 may be extended or contracted to cope with a change caused in the tilt of the grinding area 72 in its entirety by the adjustment of the adjustment shaft 62. Specifically, the thickness distribution indicated by the graph of FIG. 4A represents an example of thickness distribution that is developed if the second grindstones 20b grind the workpiece 1 to a shallow depth centrally in the grinding area 72 between the center 68 of the holding surface 8a and the outer circumferential edge 66 thereof. The difference between the thickness of the workpiece 1 at the center thereof and the thickness of the workpiece 1 at the outer circumferential edge thereof is indicated as a thickness deviation “m” in FIG. 4A. If the workpiece 1 is ground in the center of the grinding area 72 more deeply than in a peripheral area, then the thickness deviation “m” becomes a negative value.

In view of the cross-sectional shape of the workpiece 1 that is produced due to the thickness deviation “m,” the thickness deviation “m” may be called a “gull wing deviation.” The degrees to which the adjustment shafts 62 and 64 are to be adjusted may be determined to make the deviation “m” zero. As illustrated in FIG. 4A, the thickness deviation “m” can be expressed by a quadratic function of the distance from the center of the workpiece 1, represented by the horizontal axis, and the thickness deviation of the workpiece 1, represented by the vertical axis. This quadratic function means that the thickness deviation represented by the vertical axis is zero when the distance from the center of the workpiece 1 represented by the horizontal axis is zero, the thickness deviation is “m” when the distance from the center of the workpiece 1 is 0.5R, and the thickness deviation is zero when the distance from the center of the workpiece 1 is R.

In a case where the lengths of the adjustment shafts 62 and 64 are appropriate, the thickness of the workpiece 1 is uniform in its entirety. In a case where the lengths of the adjustment shafts 62 and 64 are inappropriate, the workpiece 1 develops a thickness distribution that is represented by the sum of the thickness distribution indicated by the graph of FIG. 4A and the thickness distribution indicated by the graph of FIG. 4B. Conversely, in a case where the tilt of the table rotational axis 58 is inappropriate, the thickness distribution developed by the workpiece 1 can be separated into the thickness distribution indicated by the graph of FIG. 4A and the thickness distribution indicated by the graph of FIG. 4B. The tilt adjustment variable calculating section 96 of the control unit 90 calculates degrees to which the adjustment shafts 62 and 64 are to be adjusted in order to make the thickness deviation “m” zero in the graph illustrated in FIG. 4A and also to make the thickness deviation “a” zero in the graph illustrated in FIG. 4B. The grinding controlling section 92 controls the tilt adjustment unit by referring to the degrees calculated by the tilt adjustment variable calculating section 96, to adjust the lengths of the adjustment shafts 62 and 64, thereby adjusting the tilt of the table rotational axis 58.

When the tilt adjustment variable calculating section 96 is to calculate degrees to which the lengths of the adjustment shafts 62 and 64 are to be adjusted, i.e., adjustment variables, the tilt adjustment variable calculating section 96 refers to the thickness distribution of the workpiece 1, i.e., the cross-sectional shape of the workpiece 1. The cross-sectional shape of the workpiece 1 that serves as a reference for calculating the adjustment variables varies at all times while the grinding process for the workpiece 1 is in progress. In addition, the measuring unit 42a for measuring the thickness of the workpiece 1 is unable to move into physical interference with the second grinding unit 10b, i.e., to enter the space above the central portion of the workpiece 1, and hence cannot measure the thickness of the workpiece 1 in its central portion. Consequently, the cross-sectional shape calculating section 94 of the control unit 90 measures the thicknesses of various portions of the workpiece 1 within a possible range with the measuring unit 42a of the second thickness measuring device 42, and calculates the entire cross-sectional shape of the workpiece 1 according to the measured thicknesses. In particular, the cross-sectional shape calculating section 94 calculates the cross-sectional shape of the workpiece 1 at a certain point of time, in view of the different times at which the cross-sectional shape calculating section 94 measures the thicknesses of the various portions of the workpiece 1. An example of a process of calculating the cross-sectional shape of the workpiece 1 by the cross-sectional shape calculating section 94 will be described below.

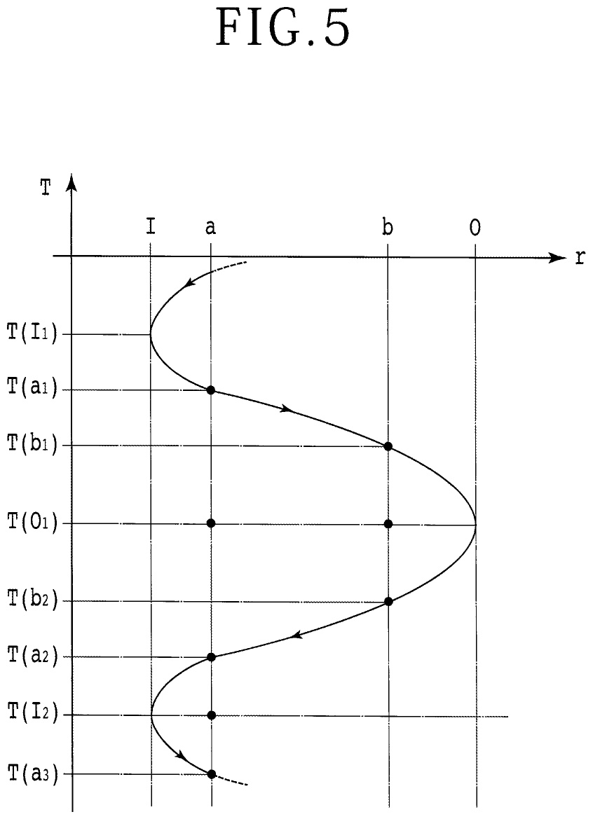

FIG. 5 is a graph illustrating the relation between the distance “r” from the center of the workpiece 1 of the measuring unit 42a that is moved by the measuring unit moving mechanism while the grinding process for the workpiece 1 is in progress and the thickness T of the workpiece 1. In the graph, the position “I” on the horizontal axis represents a position close to the center of the workpiece 1 at an end of a measuring track along which the measuring unit 42a moves. The position “O” on the horizontal axis represents a position above the outer circumferential edge of the workpiece 1 at an opposite end of the measuring track of the measuring unit 42a. The measuring unit 42a moves back and forth along the measuring track between the position “I” and the position “O” while the workpiece 1 is being ground. The vertical axis of the graph illustrated in FIG. 5 represents the thickness T of the workpiece 1 measured by the measuring unit 42a. Here, an example in which the reverse side 1b of the workpiece 1 is ground uniformly at the same grinding rate in its entirety will be described below. In FIG. 5, T(I₁) represents a value of the thickness of the workpiece 1 measured by the measuring unit 42a when the measuring unit 42a is in the position “I” on the measuring track, T(O₁) a value of the thickness of the workpiece 1 measured by the measuring unit 42a when the measuring unit 42a is in the position “O” on the measuring track, and T(I₂) a value of the thickness of the workpiece 1 measured by the measuring unit 42a when the measuring unit 42a has returned to the position “I” on the measuring track.

The grinding apparatus 2 according to the present embodiment calculates an average thickness value that represents the average value of measured thickness values acquired when the measuring unit 42a measures the thickness of the workpiece 1 in forward strokes on the measuring track and measured thickness values acquired when the measuring unit 42a measures the thickness of the workpiece 1 in return strokes on the measuring track. The significance of the calculation of the average thickness value will be described below. In one example, attention is drawn to a change in the thickness of the workpiece 1 at any position “a” on the measuring track between the position “I” and the position “O” at the respective ends thereof. After the measuring unit 42a that moves back and forth along the measuring track has left the position “I,” the measuring unit 42a passes through the position “a” when it measures a value T(a₁) of the thickness of the workpiece 1. The stroke at this time of the measuring unit 42a will be referred to as a “forward stroke” and the value T(a₁) as “measured forward stroke thickness value.” Thereafter, the measuring unit 42a, after having reached the position “O,” reverses its direction at the position “O,” and passes again through the position “a” when it measures a value T(a₂) of the thickness of the workpiece 1. The stroke at this time of the measuring unit 42a will be referred to as a “return stroke” and the value T(a₂) as a “measured return stroke thickness value.”

The speed at which the measuring unit 42a is moved back and forth on the measuring track by the measuring unit moving mechanism changes periodically. Specifically, the measuring unit 42a is accelerated after it has left the position “I” until it reaches a midpoint on the measuring track, and then decelerated from the midpoint until it reaches the position “I.” The changes in the speed of the measuring unit 42a are symmetrical upon acceleration and deceleration on both sides of the midpoint, and are similar in the forward and return strokes. Therefore, the length of time required for the measuring unit 42a to travel after it has passed through the position “a” until it reaches the position “O” and the length of time required for the measuring unit 42a to travel after it has left the position “O” until it reaches the position “a” are equal to each other. The workpiece 1 is ground at a constant rate.

Thus, the amount of the material ground off from the workpiece 1 during the period of time after the measuring unit 42a has passed through the position “a” until it reaches the position “O” and the amount of the material ground off from the workpiece 1 during the period of time after the measuring unit 42a has left the position “O” until it reaches the position “a” are equal to each other. Consequently, the average value of the thickness value T(a₁) and the thickness value T(a₂) represents the thickness of the workpiece 1 at a position underlying the position “a” on the measuring track at the time the measuring unit 42a reaches the position “O.” Similarly, at a position “b” different from the position “a” on the measuring track, the thickness value of the workpiece 1 measured by the measuring unit 42a moving in the forward stroke on the measuring track is referred to as “T(b₁),” and the thickness value of the workpiece 1 measured by the measuring unit 42a moving in the return stroke on the measuring track is referred to as “T(b₂).” The average value of the thickness value T(b₁) and the thickness value T(b₂) represents the thickness of the workpiece 1 at a position underlying the position “b” on the measuring track at the time the measuring unit 42a reaches the position “O.”

The measuring unit 42a calculates at each of various points on the workpiece 1 the average value of the measured forward stroke thickness value acquired when the measuring unit 42a measures the thickness of the workpiece 1 in the forward stroke and the measured return stroke thickness value acquired when the measuring unit 42a measures the thickness of the workpiece 1 in the return stroke. The distribution of the average values obtained at the various points is in conformity with the distribution of thickness values of the workpiece 1, i.e., the cross-sectional shape thereof, at the time the measuring unit 42a has reached the position “O.” It is important to note that this process makes it possible to obtain a thickness distribution of the workpiece 1 that is free of the effect of the differences between the measuring times. When the measuring unit 42a reaches the position “a” again after having moved in the return stroke on the measuring track and changed its direction at the position “I,” the measuring unit 42a measures the thickness of the workpiece 1 as a measured thickness value T(a₃). The measuring unit 42a may calculate an average thickness value of the thickness value T(a₂) and thickness value T(a₃). This average thickness value represents the thickness of the workpiece 1 at a position underlying the position “a” on the measuring track at the time the measuring unit 42a reaches the position “I.” In other words, a thickness distribution of the workpiece 1, i.e., a cross-sectional shape thereof, can be calculated at this time according to a similar process, and a thickness distribution of the workpiece 1, i.e., a cross-sectional shape thereof, can be calculated repeatedly according to a similar process.

In FIG. 5, the changes in the thickness of the workpiece 1 that are detected by the measuring unit 42a as it moves back and forth between the position “I” and the position “O” are represented by a curve like a sine curve. However, the curve representing the detected changes in the thickness of the workpiece 1 is not limited to such a sine curve. Strictly, the measuring track followed by the measuring unit 42a changes depending on the position of the shaft 42b of the thickness measuring device 42, the length of the arm 42c, changes over time in the rotational speed of the shaft 42b, etc., changing the shape of the curve. However, at any position on the measuring track, the thickness distribution of the workpiece 1 can be calculated insofar as the length of time required for the measuring unit 42a to travel after it has passed through the position until it reaches an end of the measuring track and the length of time required for the measuring unit 42a to travel after it has left the end of the measuring track until it passes through the position are equal to each other. In other words, as long as the measuring unit 42a moves in order to equalize those lengths of time, it is possible to calculate the thickness distribution of the workpiece 1 according to the process described above.

Since the measuring unit 42a cannot move over the central portion of the workpiece 1, the cross-sectional shape calculating section 94 cannot calculate a thickness distribution, i.e., a cross-sectional shape, of the central portion of the workpiece 1. However, it is possible to calculate a thickness distribution, i.e., a cross-sectional shape, of the central portion of the workpiece 1 according to the thickness distribution, i.e., the cross-sectional shape, of a portion of the workpiece 1 except the central portion thereof. For example, the control unit 90 may further have a cross-sectional shape interpolating section 98 for interpolating a cross-sectional shape of the workpiece 1 by calculating the cross-sectional shape of the central portion of the workpiece 1 from the cross-sectional shape of the central portion that is calculated by the cross-sectional shape calculating section 94. In this case, the tilt adjustment variable calculating section 96 calculates a degree to which the tilt of the table rotational axis 58 is to be adjusted according to the cross-sectional shape of the workpiece 1 interpolated by the cross-sectional shape interpolating section 98. For example, the cross-sectional shape interpolating section 98 derives an approximate equation representing a height distribution of the upper surface of the workpiece 1 according to the least-squares method from the cross-sectional shape of the portion of the workpiece 1 except the central portion thereof, and calculates a cross-sectional shape of the central portion of the workpiece 1 according to the approximate equation, thereby interpolating the cross-sectional shape of the workpiece 1. In this process, the approximate equation representing the height distribution of the upper surface of the workpiece 1, which is derived according to the least-squares method, also contributes to minimizing the effect of errors and variations that are necessarily caused in thickness values measured at various points on the workpiece 1 by the measuring unit 42a.

Errors and variations caused in thickness values measured at various points on the workpiece 1 by the measuring unit 42a may be corrected by a process of calculating an average thickness value per certain length on the upper surface of the workpiece 1 or a median thickness value of the workpiece 1, other than the least-squares method. In addition, errors and variations may alternatively be corrected by a process of performing a plurality of thickness measurements and calculating an average or median thickness value from the thickness measurements at various points on the workpiece 1. However, these processes other than the least-squares method will require a further process of calculating the thickness of the central portion of the workpiece 1 where no measured value can be obtained after errors and variations caused in measured thickness values have been corrected. Still another process, other than the least-squares method, of deriving a thickness distribution, i.e., a cross-sectional shape, of the central portion of the workpiece 1 may be performed by registering typical examples of a thickness distribution of the workpiece 1 in advance as a plurality of data maps in the control unit 90 and checking measured thickness values against the data maps. According to this process, the cross-sectional shape calculating section 94 calculates a thickness distribution of the portion of the workpiece 1 other than the central portion thereof, the obtained thickness distribution is checked against the data maps registered in the control unit 90, and one of the data maps that best matches the thickness distribution is selected as an entire thickness distribution of the workpiece 1.

However, the workpiece 1 that is being ground may come to have a cross-sectional shape not normally predicted because of the shape of the lower surface, not ground, of the workpiece 1, the shape of the holding surface 8a of the chuck table 8, unexpected faults of the grinding apparatus 2, etc. In other words, any of the data maps registered in the control unit 90 may fail to match the thickness distribution of the workpiece 1. On the other hand, the process of interpolating the thickness distribution, i.e., the cross-sectional shape, of the workpiece 1 according to the least-squares method is able to calculate an appropriate equation for the upper surface of the workpiece 1 and interpolate the cross-sectional shape of the workpiece 1 even in cases where the workpiece 1 has an unknown thickness distribution not normally predicted. In such cases where the workpiece 1 has an unknown thickness distribution, the tilt of the table rotational axis 58 can be corrected in order for the entire workpiece 1 to have a final uniform thickness, as described later.

The process of interpolating the thickness distribution, i.e., the cross-sectional shape, of the workpiece 1 according to the least-squares method can deal with situations where the workpiece 1 has an unknown thickness distribution as measured by the measuring unit 42a, and also reduce the effect of errors, etc., of measured values and interpolate the thickness distribution of the central portion of the workpiece 1. Further, by use of the approximate equation derived by the least-squares method for the thickness distribution of the workpiece 1, the thickness distribution of the workpiece 1 can easily be separated into the two graphs illustrated in FIGS. 4A and 4B. Specifically, it is assumed that the sum of the graph represented by the quadratic function as illustrated in FIG. 4A and the graph represented by the linear function as illustrated in FIG. 4B represents the thickness distribution of the workpiece 1. Then, according to the approximate equation derived by the least-squares method for the thickness distribution of the workpiece 1, the value of “m” in FIG. 4A and the value of “a” in FIG. 4B are calculated. Thereafter, the tilt of the table rotational axis 58 can be adjusted according to the calculated value of “m” and the calculated value of “a.”

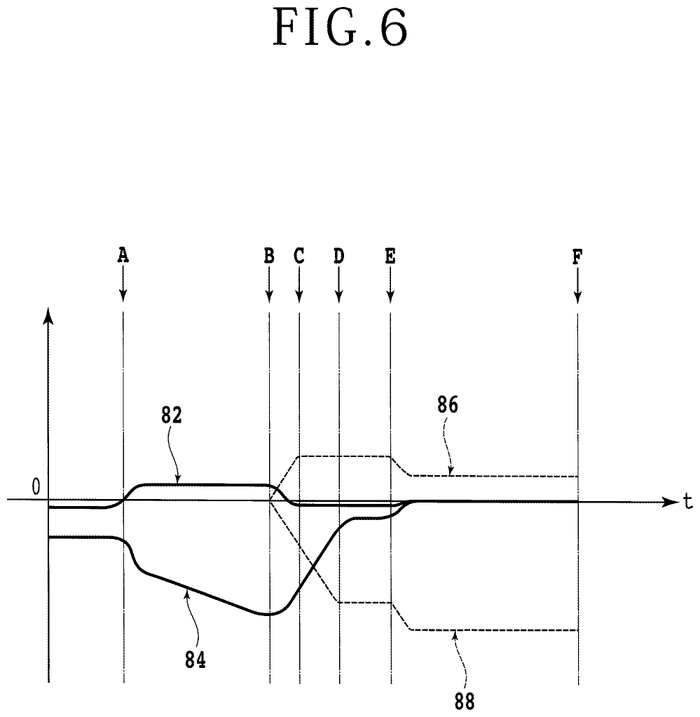

Next, a process of calculating a degree by which the tilt of the table rotational axis 58 is to be adjusted with the tilt adjustment variable calculating section 96 and grinding the workpiece 1 while adjusting the tilt of the table rotational axis 58 in order for the entire workpiece 1 to have a uniform finished thickness will be described below. FIG. 6 is a graph schematically illustrating changes over time of a deviation of the thickness of the workpiece 1 being ground and changes over time of a tilt adjustment variable for the table rotational axis 58. The graph has a horizontal axis representing time and a vertical axis representing the magnitudes of various quantities. According to the graph, the second grindstones 20b are brought into abrasive contact with the reverse side 1b of the workpiece 1 to start grinding the workpiece 1 at time A, and the second grindstones 20b stop being lowered to finish grinding the workpiece 1 at time F. In FIG. 6, a broken-line curve 86 represents changes over time of the length of the adjustment shaft 62, i.e., an adjustment variable, and a broken-line curve 88 represents changes over time of the length of the adjustment shaft 64, i.e., an adjustment variable. The solid-line curve 82 represents changes over time of the deviation of the thickness distribution of the workpiece 1 that is represented by the deviation “m” in the graph of FIG. 4A, and the solid-line curve 84 represents changes over time of the deviation of the thickness distribution of the workpiece 1 that is represented by the deviation “a” in the graph of FIG. 4B. The deviation of the thickness distribution of the workpiece 1 is calculated from the thickness distribution of the workpiece 1, i.e., the cross-sectional shape thereof, calculated by the cross-sectional shape calculating section 94 according to the measured thickness values of the workpiece 1 that are measured by the thickness measuring device 42 and interpolated by the cross-sectional shape interpolating section 98.

An example of a process in which the grinding of the workpiece 1 is kept in progress by the second grinding unit 10b will be described below with reference to FIG. 6. For starting the grinding process, the grinding controlling section 92 of the control unit 90 controls the spindle motor 12b to start rotating the second spindle 14b and controls the lifting and lowering mechanism 24b to start lowering the second spindle 14b. At time A, the second grindstones 20b are brought into abrasive contact with the reverse side 1b of the workpiece 1 to start grinding the workpiece 1. At this time, if the tilt of the table rotational axis 58 is properly adjusted, then the workpiece 1 tends to have a thickness deviation. In the graph illustrated in FIG. 6, for example, the deviation “m” indicated by the solid-line curve 82 occurs at a constant value, whereas the deviation “a” indicated by the solid-line curve 84 is progressively reduced with its absolute value being continuously on the increase. If the workpiece 1 keeps being ground in this way, the thickness deviation remains on the workpiece 1 when its grinding is completed. To avoid the thickness deviation, the tilt of the table rotational axis 58 is adjusted.

At time B, the tilt of the table rotational axis 58 starts being adjusted. The tilt adjustment variable calculating section 96 calculates length adjustment variables for the respective adjustment shafts 62 and 64 that function as the tilt adjustment unit by referring to the values of the thickness deviations “a” and “m” of the workpiece 1. The control unit 90 then changes the lengths of the adjustment shafts 62 and 64 according to the calculated length adjustment variables. Specifically, the control unit 90 starts increasing the length of the adjustment shaft 62 at time B and finishes increasing the length of the adjustment shaft 62 at time C. The thickness deviation “m” of the workpiece 1 represented by the solid-line curve 82 gradually decreases from time B and stops being reduced at time C. In the example illustrated in FIG. 6, however, as the grinding process approaches time C, the thickness deviation “m” drops to a level lower than zero, and has a negative value at time C. This is caused by the fact that the length of the adjustment shaft 62 has excessively been adjusted to an unduly increased value. Consequently, the length of the adjustment shaft 62 is slightly cut back at time E, bringing the thickness deviation “m” close to zero.

The length of the adjustment shaft 64 starts being reduced at time B, and finishes decreasing at time D. The thickness deviation “a” of the workpiece 1 represented by the solid-line curve 84 gradually increases toward zero from time B, and stops increasing at time D. In the example illustrated in FIG. 6, however, the thickness deviation “a” has not yet become zero at time D. This is because the length of the adjustment shaft 64 has not sufficiently been adjusted. Consequently, the length of the adjustment shaft 64 is further reduced at time E, bringing the thickness deviation “a” close to zero.

Thereafter, the thickness deviations “a” and “m” remain highly close to zero until time F. When the thickness of the workpiece 1 reaches a finished thickness at time F, the second spindle 14b stops being lowered, bringing the grinding process to an end. At this time, since the thickness deviations “a” and “m” are highly close to zero, the entire workpiece 1 has been ground to a finished thickness highly accurately.

The process of grinding the workpiece 1 on the grinding apparatus 2 according to the present embodiment described above will be summarized below. In the grinding apparatus 2, the chuck tables 8 in the rough-grinding region and the finish-grinding region first hold the workpieces 1 thereon. Then, the chuck tables 8 are rotated about the respective table rotational axes 58, and while the grinding wheels 18a and 18b of the grinding units 10a and 10b are being rotated about the respective axes of the spindles 14a and 14b, the spindles 14a and 14b are lowered toward the respective upper surfaces of the workpieces 1. The grindstones 20a and 20b that are moving along their annular tracks are brought into abrasive contact with the upper surfaces of the workpieces 1, starting to grind the workpieces 1.

While the workpieces 1 are being thus ground, the measuring units of the thickness measuring devices 40 and 42 measure the thicknesses of the workpieces 1 while moving back and forth on the measuring tracks out of physical interference with the grinding units 10a and 10b above the workpieces 1. Operation of only the measuring unit 42a of the thickness measuring device 42 will be described hereinbelow. The control unit 90 calculates an average thickness value that represents the average value of measured thickness values acquired when the measuring unit 42a measures the thickness of the workpiece 1 in forward strokes on the measuring track and measured thickness values acquired when the measuring unit 42a measures the thickness of the workpiece 1 in return strokes on the measuring track. Thereafter, the control unit 90 calculates a cross-sectional shape of the workpiece 1 from the average thickness values at various points on the workpiece 1. However, since the measuring unit 42a is unable to enter the space above the central portion of the workpiece 1, the measuring unit 42a cannot measure the thickness of the central portion of the workpiece 1. For calculating a cross-sectional shape of the workpiece 1, therefore, an appropriate equation representing the cross-sectional shape of the workpiece 1 may be generated by the least-squares method, the cross-sectional shape of the central portion of the workpiece 1 may be calculated according to the approximate equation, and the cross-sectional shape of the workpiece 1 may be interpolated from the cross-sectional shape of the central portion of the workpiece 1. However, the process of interpolating the cross-sectional shape of the workpiece 1 is not limited to the above details.

Thereafter, the tilt of the table rotational axis 58 is adjusted such that the workpiece 1 ground by the grindstones 20a and 20b will approach a finished shape. The adjustment variable by which the tilt of the table rotational axis 58 is to be adjusted is calculated according to the calculated cross-sectional shape of the workpiece 1. Specifically, the tilt of the table rotational axis 58 is adjusted to bring the deviations “a” and “m” of the thickness distribution of the workpiece 1 close to zero. Then, while the workpiece 1 is being ground, the tilt of the table rotational axis 58 is adjusted as required until the workpiece 1 that has a predetermined uniform finished thickness is finally obtained.

In the grinding apparatus 2 according to the present embodiment, as described above, the thickness measuring device 42 measures the thickness of the workpiece 1 that is being ground and hence has its thickness changing at all times while the thickness measuring device 42 is being moved back and forth over the workpiece 1. The control unit 90 calculates a thickness distribution of the workpiece 1, i.e., a cross-sectional shape thereof, in its entirety that is free of the effect of the differences between the times at which the thickness is measured at various points on the workpiece 1. Thus, the tilt of the table rotational axis 58 can appropriately be adjusted to make the ground workpiece 1 uniform in thickness.

The present invention is not limited to the present embodiment described above, and various changes and modifications may be made therein. According to the above embodiment, for example, it has been described that the measuring unit 42a measures thicknesses of the workpiece 1 at various points thereon while moving back and forth along the measuring track, average thickness values representing an average of thickness values measured in the forward stroke and thickness values measured in the return stroke are calculated, and a cross-sectional shape of the workpiece 1 is calculated according to the average thickness values. However, the present invention is not limited to such details. Specifically, another calculating process may be employed to calculate a thickness distribution of the workpiece 1, i.e., a cross-sectional shape thereof, in its entirety that is free of the effect of the differences between the times at which the thickness is measured at various points on the workpiece 1. For example, supposing that the grinding speed, i.e., the grinding rate, of the workpiece 1 is essentially constant, a thickness distribution of the workpiece 1 may be calculated at a certain point of time in such a manner as to be free of the effect of the differences between degrees to which the grinding of the workpiece 1 is in progress due to the differences between the times at which the thickness is measured at various points on the workpiece 1.

For example, a situation is considered for measuring the thickness of the workpiece 1 when the measuring unit 42a is positioned in the position “I” at an end of the measuring track, and then measuring the thickness of the workpiece 1 when the measuring unit 42a is positioned in a particular position on the measuring track. In this situation, the product of a length of time required for the measuring unit 42a to move from the position “I” to the particular position and the grinding speed is added to the thickness of the workpiece 1 measured by the measuring unit 42a when the measuring unit 42a is positioned in the particular position. Then, the thickness of the workpiece 1 in the particular position can be calculated at the time the measuring unit 42a was positioned in the position “I.”

In this situation, too, the cross-sectional shape calculating section 94 measures the thicknesses of the various portions of the workpiece 1 with the measuring unit 42a and calculates a cross-sectional shape of the portion of the workpiece 1 other than the central portion thereof. The cross-sectional shape interpolating section 98 calculates a cross-sectional shape of the central portion of the workpiece 1 according to the least-squares method from the calculated cross-sectional shape of the portion of the workpiece 1 other than the central portion thereof, and interpolates the cross-sectional shape of the workpiece 1. The tilt adjustment variable calculating section 96 calculates a tilt adjustment variable for the table rotational axis 58 to bring the workpiece 1 ground by the second grindstones 20b close to a finished shape according to the cross-sectional shape of the workpiece 1. According to this process, it is possible to calculate a thickness distribution of the workpiece 1, i.e., a cross-sectional shape thereof, that is free of the effect of the differences between the measuring times, simply by moving the measuring unit 42a from one end to the other of the measuring track. In this case, however, the calculations required may be more complex than the above process of calculating average thickness values.

Moreover, for example, the measuring unit 42a of the thickness measuring device 42 may have a plurality of sensors. The measuring unit 42a with the plurality of sensors may be fixed in position and the sensors can simultaneously measure thicknesses of various portions of the workpiece 1 without moving. Consequently, a thickness distribution of the workpiece 1 can be obtained without being affected by the differences between the measuring times. However, it is necessary for the grinding apparatus 2 to incorporate the thickness measuring device 42 with the plurality of sensors, tending to increase the cost of the grinding apparatus 2, and thicknesses of the workpiece 1 cannot be measured at positions where the sensors are not located.

According to the above embodiment, it has been described that the workpiece 1 is ground while the tilt of the table rotational axis 58 is being adjusted to make the workpiece 1 uniform in thickness. However, the tilt adjustment unit may not necessarily be required to adjust the tilt of the table rotational axis 58, and the tilt adjustment variable calculating section 96 may not necessarily be required to calculate tilt adjustment variables for the table rotational axis 58. In the grinding apparatus 2 according to one mode of the present invention, the tilt of the spindles 14a and 14b rather than the tilt of the table rotational axis 58 of the chuck table 8 may be variable, or both the table rotational axis 58 and the spindles 14a and 14b may be variable. Specifically, the tilt adjustment unit may adjust either the table rotational axis 58 or the spindles 14a and 14b or both for adjusting the relative tilt of the table rotational axis 58 and the spindles 14a and 14b. Then, the tilt adjustment variable calculating section 96 calculates a tilt adjustment variable for either the table rotational axis 58 or the spindles 14a and 14b or both. As a result, the tilt adjustment variable calculating section 96 calculates a tilt adjustment variable for adjusting the relative tilt of the table rotational axis 58 and the spindles 14a and 14b with the tilt adjustment unit.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding apparatus comprising:
a chuck table that has a conical holding surface for holding a workpiece thereon and that is rotatable about a table rotational axis extending centrally through the holding surface;
a grinding unit including a grinding wheel having a plurality of grindstones arranged in an annular array on a surface facing the holding surface of the chuck table, a spindle having a lower end on which the grinding wheel is mounted, and a lifting and lowering mechanism for lifting and lowering the spindle, the grinding unit being capable of grinding the workpiece held on the holding surface of the chuck table while the chuck table is rotating about the table rotational axis, in an area of the workpiece extending from a center of the workpiece to an outer circumferential edge thereof;
a tilt adjustment unit for adjusting a relative tilt of the table rotational axis and the spindle;
a thickness measuring device for measuring a thickness of the workpiece held on the chuck table; and
a control unit,
wherein the thickness measuring device includes
a measuring unit for measuring a thickness of the workpiece while facing a portion of an upper surface of the workpiece to be ground by the grinding unit, and
a measuring unit moving mechanism for moving the measuring unit back and forth on a measuring track between a position above the outer circumferential edge of the workpiece held on the chuck table and a position above the workpiece out of physical interference with the grinding unit, and
the control unit includes
a grinding controlling section for rotating the chuck table holding the workpiece thereon about the table rotational axis and controlling the lifting and lowering mechanism to lower the spindle while rotating the grinding wheel of the grinding unit about an axis of the spindle, to bring the grindstones into abrasive contact with the upper surface of the workpiece and thereby grind the workpiece,
a cross-sectional shape calculating section for controlling the measuring unit to measure thicknesses of the workpiece at various points thereon while controlling the measuring unit moving mechanism to move the measuring unit back and forth on the measuring track, calculating average thickness values representing average values of measured thickness values acquired when the measuring unit measures the thickness of the workpiece in forward strokes on the measuring track and measured thickness values acquired when the measuring unit measures the thickness of the workpiece in return strokes on the measuring track, and calculating a cross-sectional shape of the workpiece from the average thickness values at the various points, and
a tilt adjustment variable calculating section for calculating an adjustment variable for the relative tilt of the table rotational axis and the spindle to be adjusted by the tilt adjustment unit in order to bring the workpiece ground by the grindstones close to a finished shape according to the cross-sectional shape of the workpiece.

2. The grinding apparatus according to claim 1,
wherein the control unit further includes
a cross-sectional shape interpolating section for calculating a cross-sectional shape of a central portion of the workpiece according to the least-squares method from the cross-sectional shape of the workpiece calculated by the cross-sectional shape calculating section and interpolating the cross-sectional shape of the workpiece according to the calculated cross-sectional shape of the central portion of the workpiece, and
the tilt adjustment variable calculating section calculates an adjustment variable for a relative tilt of the table rotational axis and the spindle according to the cross-sectional shape of the workpiece interpolated by the cross-sectional shape interpolating section.

3. A grinding apparatus comprising:
a chuck table that has a conical holding surface for holding a workpiece thereon and that is rotatable about a table rotational axis extending centrally through the holding surface;
a grinding unit including a grinding wheel having a plurality of grindstones arranged in an annular array on a surface facing the holding surface of the chuck table, a spindle having a lower end on which the grinding wheel is mounted, and a lifting and lowering mechanism for lifting and lowering the spindle, the grinding unit being capable of grinding the workpiece held on the holding surface of the chuck table while the chuck table is rotating about the table rotational axis, in an area of the workpiece extending from a center of the workpiece to an outer circumferential edge thereof;
a tilt adjustment unit for adjusting a relative tilt of the table rotational axis and the spindle;
a thickness measuring device for measuring a thickness of the workpiece held on the chuck table; and
a control unit,
wherein the thickness measuring device includes
a measuring unit for measuring a thickness of the workpiece while facing a portion of an upper surface of the workpiece to be ground by the grinding unit, and
a measuring unit moving mechanism for moving the measuring unit back and forth on a measuring track between a position above the outer circumferential edge of the workpiece held on the chuck table and a position above the workpiece out of physical interference with the grinding unit,
the control unit includes
a grinding controlling section for rotating the chuck table holding the workpiece thereon about the table rotational axis and controlling the lifting and lowering mechanism to lower the spindle while rotating the grinding wheel of the grinding unit about an axis of the spindle, to bring the grindstones into abrasive contact with the upper surface of the workpiece and thereby grind the workpiece,
a cross-sectional shape calculating section for controlling the measuring unit to measure thicknesses of the workpiece at various points thereon while controlling the measuring unit moving mechanism to move the measuring unit back and forth on the measuring track, and calculating a cross-sectional shape of a portion of the workpiece other than a central portion thereof from measured thickness values,
a tilt adjustment variable calculating section for calculating an adjustment variable for the relative tilt of the table rotational axis and the spindle to be adjusted by the tilt adjustment unit in order to bring the workpiece ground by the grindstones close to a finished shape according to the cross-sectional shape of the workpiece, and
a cross-sectional shape interpolating section for calculating a cross-sectional shape of the central portion of the workpiece according to the least-squares method from the cross-sectional shape of the portion of the workpiece other than the central portion thereof calculated by the cross-sectional shape calculating section and interpolating the cross-sectional shape of the workpiece according to the calculated cross-sectional shape of the central portion of the workpiece, and
the tilt adjustment variable calculating section calculates an adjustment variable for the relative tilt of the table rotational axis and the spindle according to the cross-sectional shape of the workpiece interpolated by the cross-sectional shape interpolating section.

4. The grinding apparatus according to claim 1, wherein the measuring unit is a non-contact-type sensor for measuring the thickness of the workpiece while staying out of physical contact with the workpiece.

5. The grinding apparatus according to claim 1, wherein the measuring unit includes a plurality of sensors for measuring the thickness of the workpiece.
